(19) United States
(12) Patent Application Publication
(10) Pub. No.: US 2025/0351470 A1
(43) Pub. Date: Nov. 13, 2025

(54) SEMICONDUCTOR DEVICE

(71) Applicant: SANKEN ELECTRIC CO., LTD., Niiza-Shi (JP)

(72) Inventor: Hironori AOKI, Niiza-Shi (JP)

(73) Assignee: SANKEN ELECTRIC CO., LTD., Niiza-Shi (JP)

(21) Appl. No.: 19/199,520

(22) Filed: May 6, 2025

(30) Foreign Application Priority Data
May 9, 2024 (JP) 2024-076509
Apr. 30, 2025 (JP) 2025-075142

(51) Int. Cl. H10D 62/10; H10D 30/65; H10D 64/00; H10D 64/27

(52) U.S. Cl. CPC H10D 62/102; H10D 30/655; H10D 62/126; H10D 64/112; H10D 64/27

(57) ABSTRACT

A semiconductor device according to one or more embodiments may include a high potential region electrically connected with an electrode of a high potential side, a low potential region electrically connected with an electrode of a low potential side, a breakdown voltage improvement region arranged between the high potential region and the low potential region, including a first semiconductor region, field plates, each of the field plates arranged facing a surface of the breakdown voltage improvement region interposed an insulating layer, the field plates coupled each other between the high potential region and the low potential region, and extending in a direction that intersects the array direction, an auxiliary semiconductor region locally arranged corresponding to at least one field plate selected from the field plates on the surface of the first semiconductor region, and a connection electrode connecting the auxiliary semiconductor region with field plate selected from the field plates.

### CROSS REFERENCE TO RELATED APPLICATIONS

This application claims priority to prior Japanese Patent Application No. 2024-076509 filed with the Japan Patent Office on May 9, 2024, and Japanese Patent Application No. 2025-075142 filed with the Japan Patent Office on Apr. 30, 2025, the entire contents of which are incorporated herein by reference.

### BACKGROUND

The disclosure relates to a semiconductor device including a structure in which electric field concentration is suppressed by the use of a field plate structure.

A depletion layer may spread in the lateral direction between the drain and gate in the power semiconductor device of the lateral double diffused type, or in the terminal region arranged around the semiconductor substrate on which the power semiconductor circuit (IGBT, etc.) is arranged. At this time, a structure is used that improves the breakdown voltage to increase the breakdown voltage by suppressing the increase in the electric field strength locally and equalizing the electric field strength. As a structure for improving the breakdown voltage, a field plate may be used in a semiconductor device.

Such a structure is described in the Japanese patent publication No. 2010-157760 (Patent document 1), and Japanese patent No. 3275964 (Patent document 2). In the patent documents 1 and 2, a plurality of field plates (first field plate: conductive layer facing the surface of the semiconductor layer interposed an insulating layer) are arranged between the high potential side and the low potential side on the drift layer in the lateral MOSFET. Each first field plate is electrically insulated. Further, the first field plate on the highest potential (e.g. drain) side may be connected to a high potential electrode, and the first field plate on the lowest potential (e.g. gate) side may be connected to a low potential electrode. The other first field plates, for example, may all be floating. Furthermore, on the upper side between the first field plates, the second field plate on the upper layer side is arranged in the same arrangement interposed an insulating layer. Similarly, the second field plate may all be floating. In this configuration, there is capacitance coupling between the first field plates, between the second field plates, or between the first field plate and the second field plate. In addition, there is capacitance coupling between the high potential electrode and the first field plate, or between the high potential electrode and the second field plate are capacitively coupled. Furthermore, there is capacitive coupling between the low potential electrode and the first field plate, or between the low potential electrode and the second field plate. Therefore, the entire field plate, including the first and second field plates, is capacitively coupled to a high potential electrode and capacitively coupled to a low potential electrode. In the structure described in the patent document 2, each field plate is arranged in concentric rings surrounding the drain region. In addition, the upper part of the field plate is covered with a protective film (insulating layer), and the floating state of each field plate is ensured.

When the field plate is used, the surface potential of the semiconductor layer directly below the field plate is affected by the potential of the field plate above it. For this reason, the surface potential is adjusted so that the surface potential directly under the common field plate is forced to be common, and the increase in local field strength is suppressed. In particular, when a two-layer field plates array is used as described above, the surface of the semiconductor layer may be covered with a field plate with a small exposure from a planar view, and the capacity between the field plates may be easily adjusted. For this reason, the surface potential difference of the semiconductor layer is divided into appropriate intervals, which is particularly effective in improving the breakdown voltage.

### SUMMARY

A semiconductor device according to one or more embodiments may include a high potential region electrically connected with an electrode of a high potential side; a low potential region electrically connected with an electrode of a low potential side; a breakdown voltage improvement region arranged between the high potential region and the low potential region, comprising a first semiconductor region of a first conductive type; a plurality of field plates, each of the field plates arranged facing a surface of the breakdown voltage improvement region interposed an insulating layer, the field plates arranged in an array direction so as to capacitively coupled each other between the high potential region and the low potential region, and extending in a direction that intersects the array direction; an auxiliary semiconductor region of a second conductive type locally arranged corresponding to at least one field plate selected from the field plates on the surface of the first semiconductor region; and a connection electrode connecting the auxiliary semiconductor region with the field plate selected from the field plates.

### BRIEF DESCRIPTION OF DRAWINGS

FIG. 1 is a diagram illustrating a plan view of a structure of a semiconductor device according to one or more embodiments.

FIG. 2 is a diagram illustrating a cross-sectional view of a first part of a semiconductor device according to one or more embodiments.

FIG. 3 is a diagram illustrating a top view of an enlarged portion of a semiconductor device according to one or more embodiments.

FIG. 4 is a diagram illustrating a cross-sectional view of a second part of a semiconductor device according to one or more embodiments.

FIG. 5 is a diagram illustrating a cross-sectional view of a third part of a semiconductor device according to one or more embodiments.

FIGS. 6A, 6B, 6C, 6D are diagrams illustrating plan views of an arrangement of auxiliary semiconductor regions in a semiconductor device as an example according to one or more embodiments.

FIG. 7 is a diagram illustrating an enlarged top view in which a part of a first modification of a semiconductor device according to one or more embodiments.

FIG. 8 is a diagram illustrating a cross-sectional view of a first modification of a semiconductor device according to one or more embodiments.

FIG. 9 is a diagram illustrating a cross-sectional view of a second modification of a semiconductor device according to one or more embodiments.

FIG. 10 is a diagram illustrating a cross-sectional view of a third modification of a semiconductor device according to one or more embodiments.

FIG. 11 is a diagram illustrating a cross-sectional view of a fourth modification of a semiconductor device according to one or more embodiments.

FIG. 12 is a diagram illustrating a cross-sectional view of a fifth modification of a semiconductor device according to one or more embodiments.

FIG. 13 is a diagram illustrating a plan view of a sixth modification of a semiconductor device according to one or more embodiments.

FIG. 14A is a diagram illustrating a result of calculating a current-voltage characteristics of a conventional semiconductor device by simulation, and FIG. 14B is a diagram illustrating a result of calculating a current-voltage characteristics in a sixth modification of the semiconductor device according to one or more embodiments.

FIGS. 15A and 15B are diagrams illustrating cross-sectional views of a seventh modification of a semiconductor device according to one or more embodiments.

### DETAILED DESCRIPTION

Hereinafter, a semiconductor device comprising one or more embodiments is described. In the description of the following drawings, the same or similar parts are denoted by the same or similar numerals. However, it should be noted that the drawings are schematic, and the relationship between the thickness and the planar dimensions, the ratio of the length of each part, etc. are different from the real ones. Therefore, the specific dimensions should be judged with reference to the following explanation. In addition, it is of course the case that there are parts where the relationship and proportions of the dimensions of each other are different between the drawings. Further, the embodiment shown below illustrates a device for embodying the technical idea of the disclosure, and the technical idea of the disclosure does not specify the shape, structure, arrangement, etc. of the component parts as follows. In the present disclosure, terms that specify the upper and lower parts such as the term “above” and the term “below” are used for the convenience of description, and even if they are provided on the side, if they are substantially the same as the constituent requirements of the disclosure, they belong to the technical scope of the disclosure. In addition, the term “above” and the term “on” include not only the case where it is arranged in contact with the object, but also the case where it is arranged through another layer. In the disclosure, the term “connection” is not limited to direct connection, and even if it is connected by intervening something such as a resistor in between, it belongs to the scope of the right of the disclosure as long as it is substantially the same as the constituent requirements of the present disclosure. In addition, the X axis, the Y axis, the Z axis, or a combination thereof may be displayed in the figure, and “X axis direction”, “Y axis direction”, and “Z axis direction” may be used in the specification or drawing to describe the direction.

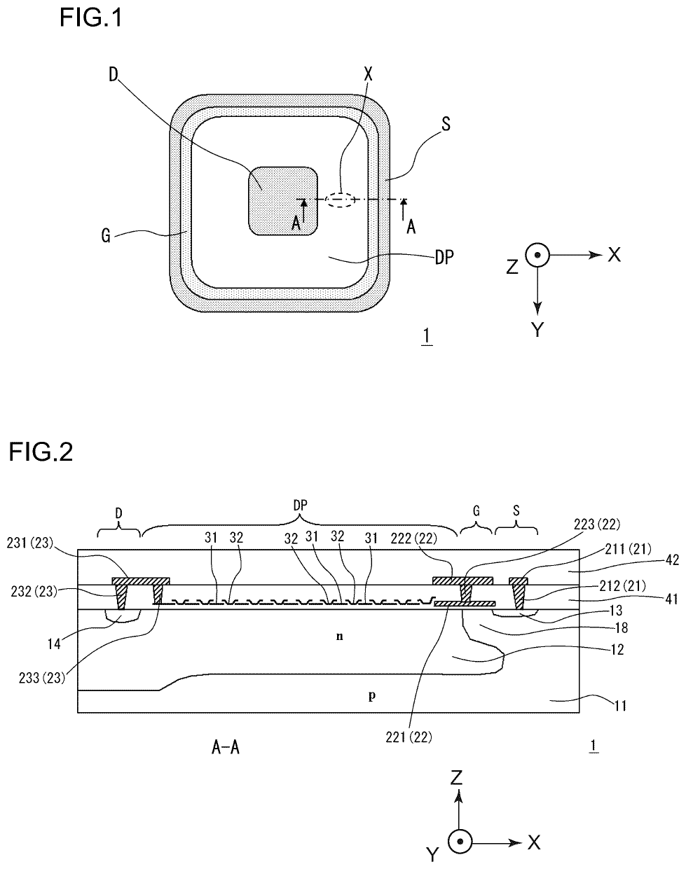

FIG. 1 is a diagram showing a schematic of the planar structure of the semiconductor device 1 according to one or more embodiments. As an example of a semiconductor device, Lateral double diffused metal oxide semiconductor field effect transistor (LDMOSFET) is described here. The drain D of the semiconductor device 1 is provided in the center, and the gate G and the source S are arranged in a ring shape surrounding outside the drain D. Here, a planar region in the semiconductor substrate including the drain (D: high potential region), the gate (G: low potential region), and the source(S) is shown, and these do not necessarily correspond to the planar shape of the drain electrode, the gate electrode, and the source electrode, respectively. Here, the surface side of the semiconductor substrate between the gate G and the drain D becomes the drift layer of the MOSFET, and when it is off, a depletion layer is arranged in the lateral direction (between the gate G and the drain D) in the drift layer, which is the breakdown voltage improvement region DP. In order to increase the breakdown voltage when the semiconductor device 1 is turned off, it may be necessary to suppress the generation of region where the electric field intensity increases locally in the breakdown voltage improvement region DP.

FIG. 2 is a cross-sectional view in the Y axis direction perpendicular to A-A direction of FIG. 1 of a portion corresponding mainly to the drift layer (breakdown voltage improvement region DP) in the semiconductor device 1. In the semiconductor device 1, in the P-type layer 11 that is a base body, the N-type layer (first semiconductor region) 12 that serves as the drift region, the P-type layer 18 that serves as the body layer in which the channel is generated, and the N+ layer 13 that is n-type with high impurity concentration that serves as the source region on the P-type layer 18. The source electrode 21 is connected to the N+ layer 13, and a gate electrode 22 is arranged on a thin gate oxide film on the P-type layer 18. Further, an N+ layer 14 is arranged on the N-type layer 12 separated from the gate electrode 22, and the drain electrode 23 is connected to the N+ layer 14.

Between the gate electrode 22 and the N+ layer 14, the first field plate 31 of the first layer and the second field plate 32 of the second layer are arranged so that they are each surrounded by the first insulating layer 41. Similar to the structure described in the patent document 2, in a planar view, the edge side of the second field plate 32 oppositely overlaps with the edge of the first field plate 31. For this reason, in the structure of FIG. 2, at least any of the adjacent first field plates 31, or adjacent second field plates 32, or between the first field plate 31 and the second field plate 32 is capacitively coupled. Note that the first field plate 31 and the second field plate 32 are in a floating state, but the first field plate 31 or the second field plate 32 on the left side (the side closest to the drain) in the figure may be connected to the drain electrode 23, and the first field plate 31 or the second field plate 32 on the right side (the side closest to the gate) in the figure may be connected to the gate electrode 22. The first field plate 31 and the second field plate 32 may be both composed of, for example, conductive polycrystalline silicon doped with impurities at a high concentration. Thus, the plurality of field plates used here are divided into a first field plate group consisting of a first field plate 31 and a second field plate group consisting of a second field plate 32. The above points are the same as the techniques described in the patent document 2. In these cross-sectional views, including the cross-sectional views described later, the number of each field plate and the components related thereto (P+ layer 15, etc. described later) are described differently from the actual one for the explanatory purpose.

The source electrode 21 includes the source interconnection 211 in an upper portion that functions as a source interconnection, and the source electrode connection point 212 in a lower portion that is a via interconnection portion connected to the N+ layer 13. Similarly, in the drain electrode 23, the drain interconnection 231, the drain electrode connection point 232 (the portion connected to the N+ layer 14), and the drain electrode connection point 233 (the portion connected to the leftmost first field plate 31) are included. The gate electrode 22 includes the gate electrode facing part 221 that is a portion opposing the P-type layer 18, a gate interconnection 222, and a gate electrode connection point 223. The gate electrode 22 is connected to the rightmost right most first field plate 31 outside the range shown. The source electrode connection point 212, the gate electrode facing part 221, the gate electrode connection point 223, the drain electrode connection point 232, the drain electrode connection point 233, the first field plate 31, and the second field plate 32 are arranged in the first insulating layer 41 on the lower side. On the other hand, the upper source interconnection 211, the drain interconnection 231, and the gate interconnection 222 are arranged in the second insulating layer 42 on the upper side of the first insulating layer 41. The second insulating layer 42 is a layer that provides surface protection.

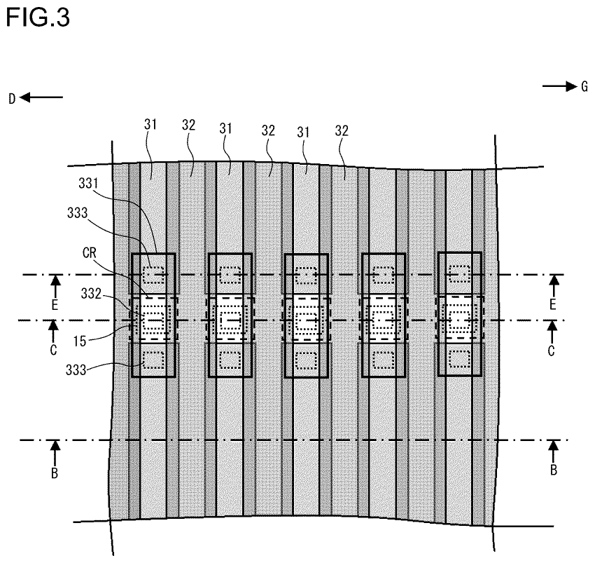

FIG. 3 is a plan view in which the region X of FIG. 1 is enlarged. In FIG. 3, in particular, the first field plate 31, the second field plate 32, the P+ layer 15 (auxiliary semiconductor region) described later, connection point 332 for the connection electrode, connection point 333 for the connection electrode, and only the structures related thereto are shown. Both the first field plate 31 and the second field plate 32 are arranged in a ring surrounding the drain (D) in the same manner as the gate (G) and the source(S) in FIG. 1, and within the range shown in FIG. 3, they extend parallel to the vertical direction in the figure. With respect to this extending direction, the P+ layer 15 is shorter than the first field plate 31 and the second field plate 32. The cross-section of FIG. 2 corresponds to the cross-section in the B-B direction (a place where the P+ layer 15 and connection point 332 and 333 for the connection electrode are not provided) in FIG. 3.

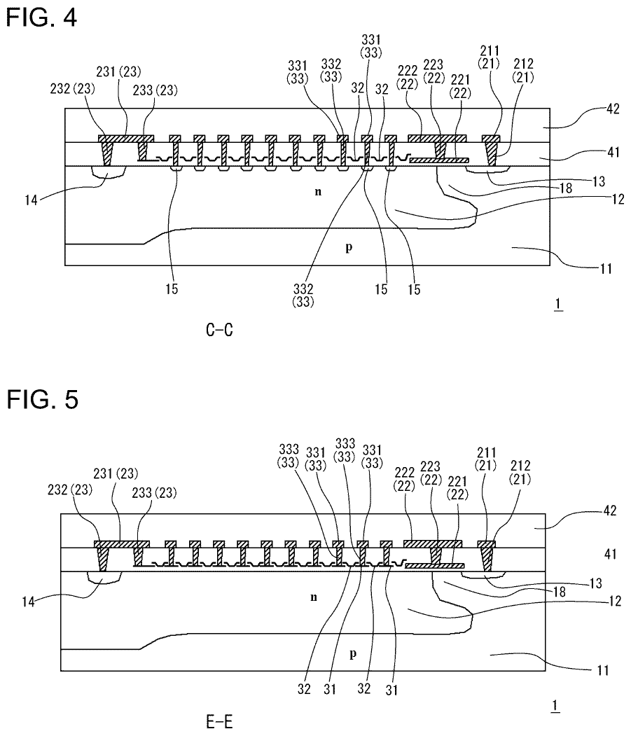

In FIG. 3, a region (connection region CR) is provided in which the first field plate 31 is locally cut out and does not exist in the extension direction of the first field plate 31. The connection region CR is provided in a horizontal line in FIG. 3. FIG. 4 is a cross-sectional view corresponding to the C-C direction including the connection region CR. In the connection region CR, the P+ layer (auxiliary semiconductor region) 15 is arranged locally directly under the region where there is no first field plate 31. Further, a connection electrode 33 connected to the P+ layer 15 is provided, and FIG. 4 corresponds to a cross-section of a place where the P+ layer 15 and the connection electrode 33 (connection point 332 for the connection electrode) are connected. For example, the width of P+ layer 15 (the length in the left-right direction in FIG. 4) may be narrower than the width of first field plate 31, and the depth of P+ layer 15 may be equal to that of N+ layer 13 or N+ layer 14, or may be formed simultaneously with the same depth as a P+ contact region of another semiconductor device such as a P-type MOSFET. The impurity concentration of the N-type layer 12 may be increased, and P+ layer 15 may be formed deeper than N+ layer 13 or N+ layer 14.

The connection electrode 33 is connected to a first field plate 31 close to the P+ layer 15. FIG. 5 is a cross-sectional view of a place where these are connected, and a cross-sectional view in the E-E direction of FIG. 3. As shown in FIGS. 3 and 4, the connection electrode 33 is connected to the connection portion of the first field plate 31 close to the p+ layer 15 so as to sandwich the connection region CR from both circumferential sides (the top and bottom directions of FIG. 3). The connection electrode 33 includes the interconnection 331 provided on the first insulating layer 41 (in the second insulating layer 42) as shown in FIGS. 4 and 5, and a connection point 332 for the connection electrode that is a via interconnection that connects the P+ layer 15 and the interconnection 331 as shown in FIG. 4.

As shown in FIGS. 3 and 5, the interconnection 331 extends not only in the connection region CR but also beyond the connection region CR in the circumferential direction of the first field plate 31 (vertical direction in the figure of FIG. 3). The interconnection 331 is connected to the first field plate 31 by the connection point 333 for the connection electrode that serves as via interconnection. In order to provide a connection electrode 33 (interconnection 331) on the upper side of the first field plate 31 and connect it to the first field plate 31, a connection region CR in which the first field plate 31 is partially removed is provided. Thereby, the above structure is realized. If the connection electrode connected to the auxiliary semiconductor region is arranged on the lower side of the first field plate, it may not be necessary to provide a region in which the first field plate is partially removed if the first field plate is arranged so as to cover the connection electrode. That is, the relationship between the auxiliary semiconductor region, the connection electrode, and the first field plate may be realized in the structure other than that shown in FIG. 3.

In FIGS. 4 and 5, each connection point (connection point 333 for the connection electrode, drain electrode connection point 232, 233, gate electrode connection point 223, source electrode connection point 212) and each interconnection (interconnection 331, drain interconnection 231, gate interconnection 222, source interconnection 211) may each be arranged with the same metal layer.

The P+ layer 15 and the connection electrode 33 are described. The depletion layer generated in the N-type layer 12 when the semiconductor device 1 is off extends from both the boundary between the N-type layer 12 and the P-type layer 11 and the boundary between the N-type layer 12 and the P-type layer 18. When the depletion layer reaches the P+ layer 15, the depletion layer also spreads to the interface between the P+ layer 15 and the N-type layer 12, but the P+ layer 15 is set at a concentration that does not completely deplete. A portion of the P+ layer 15 that is not depleted is connected to the connection electrode 33. For this reason, the potential of the first field plate 31 connected to the connection electrode 33 is not a potential determined by potential distribution by capacitive coupling, but is uniquely determined to a predetermined potential by the potential structure inside the semiconductor. When the depletion layer further expands and the depletion layer reaches the P+ layer 15 adjacent to the N+ layer 14 side, the potential of the first field plate 31 connected to the P+ layer 15 interposed the connection electrode 33 is uniquely determined to a predetermined potential different from the previous one. When the depletion layer further expands and the depletion layer reaches the P+ layer 15 adjacent to the N+ layer 14 side, the potential of the first field plate 31 connected to the P+ layer 15 interposed the connection electrode 33 is uniquely determined to a predetermined potential different from the above. This process is repeated.

In addition, it may be desirable that the P+ layer 15 is arranged in a relatively narrow range with respect to the N-type layer 12 to the extent that the connection electrode 33 may be connected to the P+ layer 15, and that the effect on the depletion layer spreading in the N-type layer 12 is small. Further, in order to prevent the entire P+ layer 15 from being depleted, the impurity concentration is sufficiently higher than that of the N-type layer 12, for example, 1×10¹⁹ cm⁻³ or more, 5×10²¹ cm⁻³ or less.

The potential of the first field plate 31 extracted from the P+ layer 15 reached by the depletion layer spreading in the N-type layer 12 is uniquely determined. For this reason, for example, even when an impurity ion (foreign ion) is adsorbed from the outside of the semiconductor device 1 on the second insulating layer 42, the potential of the first field plate 31, whose potential is uniquely determined, is not easily affected. Further, even when an impurity ion (foreign ion) is adsorbed from the outside of the semiconductor device 1 on the second insulating layer 42, the potential distribution is less affected than in the case where the impurity ion (foreign ion) is adsorbed from the outside. That is, the effect of increasing the breakdown voltage of the semiconductor device 1 may be stably maintained. In one or more embodiments, it may be preferrable that the P+ layer 15 is connected to the first field plate 31 on the high voltage side close to the P+ layer 15. This may allow the potential of the first field plate 31 on the high voltage side to affect the surface potential of the semiconductor layer, further extending the depletion layer on the surface side of the semiconductor layer to the high voltage side, thereby stably maintaining the effect of further increasing the breakdown voltage of the semiconductor device 1.

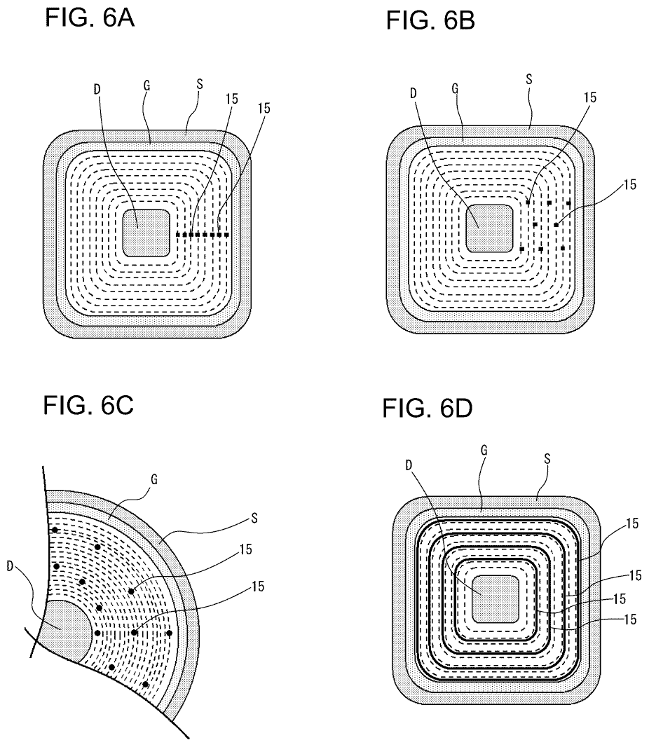

In the structure of FIG. 3, the P+ layer 15 (where the local potential is taken out) is provided in a straight line in the transverse direction (drain (D) to gate (G) direction in FIG. 1). The arrangement of the P+ layer 15 may be set appropriately. FIG. 6 is a diagram showing the position of the P+ layer 15 in the configuration of FIG. 1, and each dashed line in the figure schematically indicates that each first field plate 31 (or second field plate 32) surrounds the drain D. The shape of each first field plate 31 (or second field plate 32) is substantially annular. The P+ layer 15 of FIG. 6A is arranged in a straight line between the drain (D) and the gate (G).

In the case of FIG. 6A, since the adjacent P+ layers 15 are close together, there is a risk of affecting the spread of the depletion layer generated in the N-type layer 12. On the other hand, as shown in FIG. 6B, the effect may be reduced when the P+ layers 15 are staggered in the drain (D) to gate (G) direction so as to widen the spacing between adjacent P+ layers. Further, as shown in FIG. 6C, when the overall shape is circular, each P+ layer 15 may be distributed circumferentially and/or radially arranged and connected to each first field plate 31.

As shown in FIG. 6D, each of the P+ layers 15 may be formed in a concentric ring shape surrounding the drain (D) along the first field plate 31 (or the second field plate 32). In one or more embodiments, the connection electrodes 33 may be provided in a ring shape like each p+ layer 15, or may be arranged at one, four, six, eight, or several tens of equal intervals in the circumferential direction of the first field plate 31. Each of the P+ layers 15 may be provided in a ring shape surrounding the drain (D), and the first field plate 31 (or the second field plate 32) and the P+ layer 15 are connected via the connection electrodes 33. As a result, even if impurity ions (foreign ions) are adsorbed onto the second insulating layer 42 from the outside of the semiconductor device 1, the potential of the first field plate 31 may be less susceptible to the influence. That is, the effect of increasing the withstand voltage of the semiconductor device 1 may be maintained more stably. In one or more embodiments, the p+ layers 15 may not have to be formed uniformly over the entire circumference of a ring shape, and may be partially divided in the circumferential direction.

In FIGS. 6A and 6B, each P+ layer 15 is provided only in the right side of the drain (D) in the figure, but each P+ layer 15 may also be provided on the upper side, the left side, the lower side, and the like of the drain (D) in the figure. Further, with respect to the extension direction of the first field plate 31 (or the second field plate 32), the P+ layer 15 is shorter than the first field plate 31 and the second field plate 32, and a ratio of the P+ layer 15 to the first field plate 31 or the second field plate 32 is, for example, to 1/10 or less, more preferably 1/100 or less. In FIGS. 6A to 6D, the P+ layers 15 may not have to be arranged at equal intervals in the direction (radial direction) from the drain (D) to the gate (G). For example, the intervals of the P+ layers 15 may gradually increase. As another example, the intervals of the P+ layers 15 may gradually decrease. As yet another example, the intervals of the P+ layers 15 may gradually increase near the middle between the drain (D) and the gate (G) may gradually decrease toward at least one of the drain (D) side and the gate (G) side. As yet another example, the P+ layers 15 connected to each of all the first field plates 31 may not have to be provided, and one or more pairs of the first field plates 31 connected to the p+ layers 15 and one or more pairs of the first field plates 31 not connected to the p+ layers 15 may be repeated in the direction (radial direction) from the drain (D) to the gate (G).

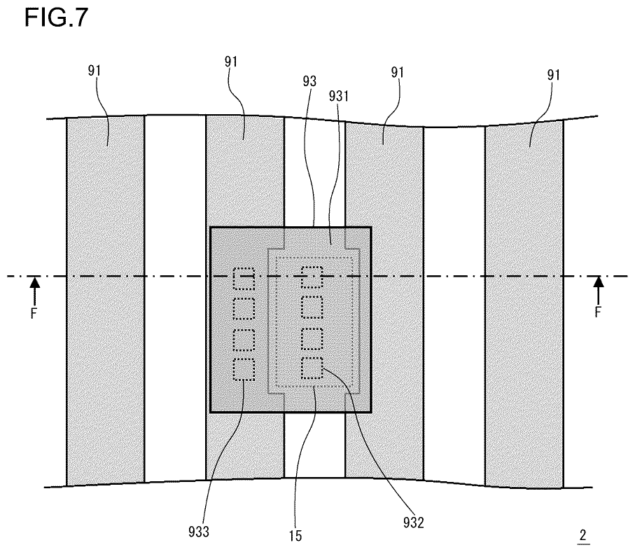

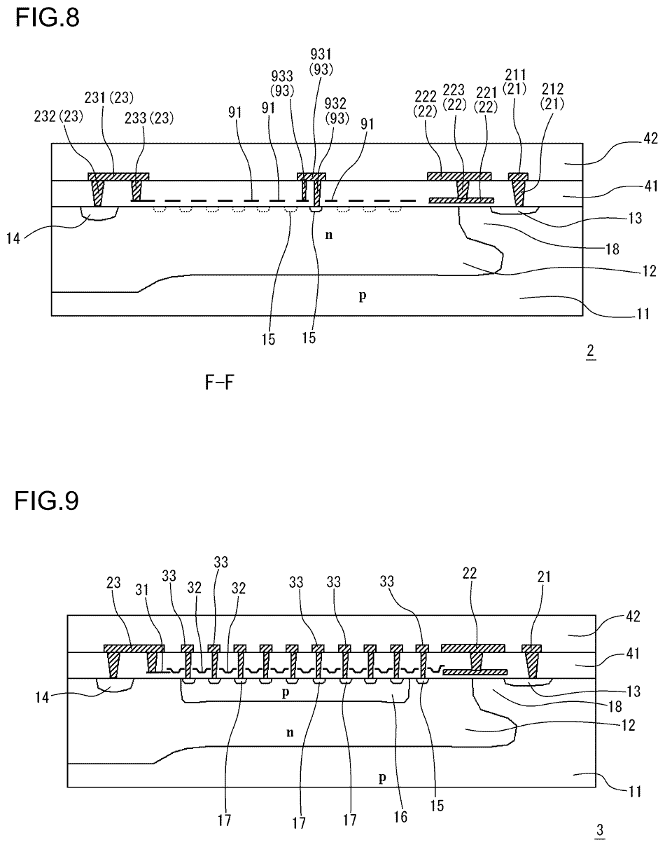

A modification of a semiconductor device according to one or more embodiments is described. In the semiconductor device 1, as shown in FIG. 3, the first field plate 31 and the second field plate 32 are provided, and the P+ layer 15 corresponding to the first field plate 31 is connected. Here, a connection region CR is provided in which the first field plate 31 is locally cut out, and the P+ layer (auxiliary semiconductor region) 15 and the connection electrode 33 are provided. In contrast, in the semiconductor device 2, which is the first modification shown in FIGS. 7 and 8, only one type of field plate 91 corresponding to the first field plate 31 is used. In other words, the second field plate 32 may not be provided, and multiple field plates 91 of same type are arranged at a distance from each other in the direction (radial direction) from the drain (D) to the gate (G), and each field plate 91 is arranged to surround the drain (D) in a planar view.

In this case, the P+ layer 15 may be provided at a location adjacent to the field plate 91 in planar view, and the P+ layer 15 and the field plate 91 may be connected using a connection electrode. In one or more embodiments, it may be preferrable that P+ layer 15 is connected to the high voltage side field plate 91 close to the P+ layer 15 using a connection electrode. FIG. 7 is a diagram corresponding to FIG. 3 showing the planar structure in this case. FIG. 8 is a cross-sectional view corresponding to the F-F direction in FIG. 7. Here, the P+ layer 15 is arranged between the adjacent field plates 91 and is connected by the connection electrode 93 to the adjacent field plate 91 on the left side of the P+ layer 15 in FIG. 7. At this time, as in the structure of FIGS. 4 and 5, the connection electrode 93 includes the connection interconnection 931 arranged on the upper side of the field plate 91, the connection point 932 for the connection electrode connected to the P+ layer 15, and the connection point 933 for the connection electrode connected to the field plate 91.

In this structure, it may be difficult to form the P+ layers 15 in a row as shown in FIG. 6A, but the structure of FIG. 7 may be easily realized by arranging the P+ layers 15 as shown in FIGS. 6B and 6C. In one or more embodiments, the p+ layer 15 is arranged as shown in FIG. 6D. According to the arrangement, even if impurity ions (foreign ions) are adsorbed onto the second insulating layer 42 from the outside of the semiconductor device 2, the potential of the field plate 91 may be less susceptible to the influence. In other words, the effect of increasing the breakdown voltage of the semiconductor device 2 may be maintained more stably. Further, it may not be necessary to cut and divide the field plate 91 as in the connection region CR, but as shown in FIG. 7, each field plate 91 is partially cut in the width direction above both sides of the P+ layer 15 to make the field plate 91 locally thinner and provide a wider spacing locally in the extending direction. Thereby, this structure may be easily realized. However, even if the width of the field plate 91 is constant, when the P+ layer 15 and the connection electrode 93 is formed without problems, it may not be necessary to make the field plate 91 thinner locally in this way.

Next, a second modification according to one or more embodiments is described. The semiconductor device 1 is an LDMOSFET having an N-type layer 12 on the P-type layer 11 as a drift layer. In one or more embodiments, it may also be adapted in a double reduced surface field structure in which the p layer is arranged on the surface of the drift layer (N-type layer 12). FIG. 9 is a cross-sectional view corresponding to FIG. 4 showing the structure of the semiconductor device 3 that is such a first modification. Here, a P-type layer (breakdown voltage improvement region) 16 having a lower concentration than the P+ layer 15 is arranged on the surface of the N-type layer 12, a plurality of N+ layers (auxiliary semiconductor region) 17 are arranged locally on the P-type layer 16, and the N+ layer 17 and the first field plate 31 are connected in the same manner as described above interposed the connection electrode 33. In this case, the depletion layer spreads from the interface between the N-type layer 12 and the P-type layer 16 when it is off. When the depletion layer in the P-type layer 16 further expands and the depletion layer reaches the N+ layer 17, the depletion layer also spreads to the interface between the P-type layer 16 and the N+ layer 17, but the N+ layer 17 is set at a concentration that may not completely deplete. Since the connection electrode 33 is connected to the non-depleted N+ layer 17, the potential of the first field plate 31 connected to the connection electrode 33 is uniquely determined at a predetermined potential. When the depletion layer reaches the adjacent N+ layer 17, the potential of the first field plate 31 connected to the N+ layer 17 interposed the connection electrode 33 is uniquely determined to a predetermined potential different from the above. The concentration of the N+ layer 17 may be, for example, 1×10¹⁹ cm⁻³ or more, or 5×10²¹ cm⁻³ or less. In the semiconductor device 3, as in the semiconductor device 1, for example, even when an impurity ion (foreign ion) is adsorbed from the outside on the second insulating layer 42, the potential of the first field plate 31 that is uniquely determined may mitigate the effect, and the potential distribution may be possible with relatively small change. That is, the effect of increasing the breakdown voltage of the semiconductor device 3 may be stably maintained.

In the semiconductor devices 1 and 3, each connection electrode 33 was connected to the first field plate 31 at the site where each was arranged. However, it is clear that the same effect may be achieved when connected to the second field plate 32 instead of the first field plate 31. However, if the first field plate 31 is closer to the semiconductor surface than the second field plate 32, the effect of increasing the breakdown voltage of the semiconductor device 1 and 3 may be more stably maintained if each connection electrode 33 is connected to the first field plate 31. Further, both a connection electrode 33 connected to the first field plate 31 and a connection electrode 33 connected to the second field plate 32 may be provided.

Alternatively, the same effect may be obtained even if the second field plate 32 is not provided in the structure of the semiconductor devices 1 and 3 and is arranged only with the field plate 91 as in the semiconductor device 2.

In the semiconductor devices 1 and 3, all first field plates 31 (or second field plates 32) are connected to the P+ layer 15 or N+ layer 17 with each connection electrode 33. However, it may not be necessary to provide the P+ layer 15 or the N+ layer 17 corresponding to all first field plates 31 (or second field plates 32).

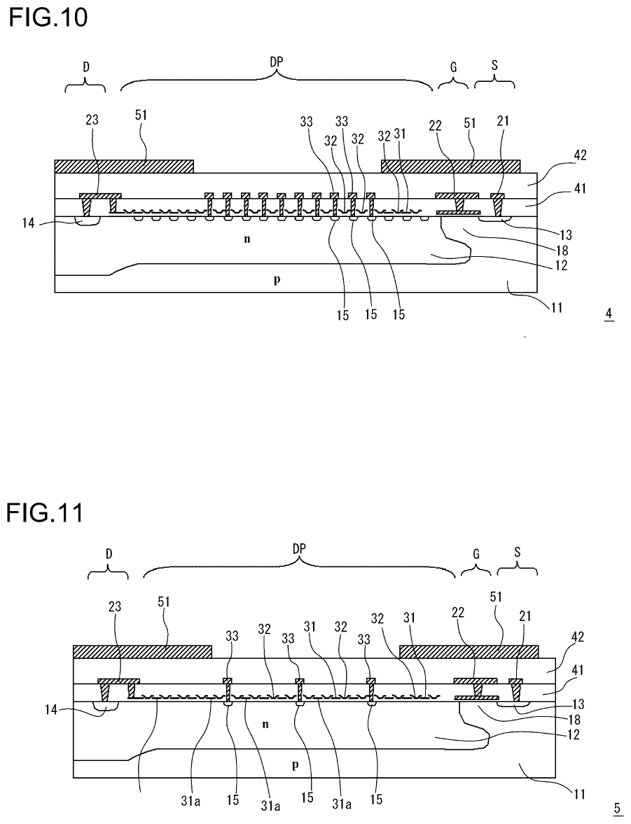

FIG. 10 is a cross-sectional view corresponding to FIG. 4 showing the structure of the semiconductor device 4 as a third modification according to one or more embodiments. In this structure, a metal plate (cover metal) 51 composed of a metal layer is arranged on the second insulating layer 42 on the high potential side (left side in the figure) and the low potential side (false side in the figure), the P+ layer 15 is provided directly under the cover metal 51. In one or more embodiments, the P+ layer 15 may not have to be provided below the cover metal 51. Also, the cover metal 51 may be provided across multiple adjacent first field plates 31 (or second field plates 32). The first field plates 31 (or second field plates 32) are not connected to the P+ layer 15 below the cover metal 51. In this case, since the influence of impurity ions (foreign ions) in the region directly below is suppressed by the cover metal 51, it may not be necessary to provide the P+ layer 15 in this region. As described above, by providing the P+ layer 15, there is a possibility that the spread of the depletion layer spreading in the N-type layer 12 may be affected, but this effect may be reduced by providing the cover metal 51.

FIG. 11 is a cross-sectional view corresponding to FIG. 4 showing the structure of the semiconductor device 5 as a fourth modification according to one or more embodiments. In this structure, the same cover metal 51 as described above is arranged, and the P+ layer 15 is not provided directly under the cover metal 51. Further, this structure corresponds to the case where the P+ layer 15 and the connection electrode 33 are connected to each first field plate 31 in a row as shown in FIG. 6A. For this reason, in the case of FIG. 6A, the P+ layer 15 (and the connection electrode 33) corresponding to all the first field plates 31 are arranged, whereas here, the P+ layer 15 is arranged only at three separated locations, and the P+ layer 15 is connected to the corresponding first field plate 31 (FIG. 11 is a cross-section of the connection region CR, so it is not shown in FIG. 11). For this reason, the corresponding P+ layer 15 is not arranged with respect to the other first field plate 31a, and the first field plate 31a is held to a floating potential in the same manner as the field plate in the conventional technology. However, the first field plate 31a and the first field plate 31 connected to the P+ layer 15 are capacitively coupled. For this reason, high breakdown voltage may be achieved by this structure as well. That is, it may not be necessary to provide P+ layers 15 for all first field plates 31 and connect them to each other. In one or more embodiments, the structure of the semiconductor device 5 is not limited to the structure shown in FIG. 6A. The P+ layers 15 and connection electrodes 33 arranged in a staggered pattern in the drain (D) to gate (G) direction as shown in FIG. 6B, the overall shape of the P+ layers 15 and connection electrodes 33 is circular as shown in FIG. 6C, alternatively the P+ layers 15 are ring-shaped as shown in FIG. 6D, it may not necessary to provide P+ layers 15 connected to each of all of the first field plates 31, and it may also not necessary to provide a P+ layer 15 directly below the cover metal 51.

In the semiconductor devices 4 and 5, the cover metal 51 may be connected to either the source electrode 21 or the drain electrode 23, or may be at floating potential. Further, in FIG. 11, one or more cover metals 51 may be further provided between the cover metals 51 on the second insulating layer 42. For example, when there are no field plates 31 and 32 directly above the P+ layer 15, it may be a structure covered with an additional cover metal directly above the P+ layer 15 between the cover metal 51. By this, the influence of impurity ions (foreign ions) on the potential of the p+ layer 15 may be suppressed.

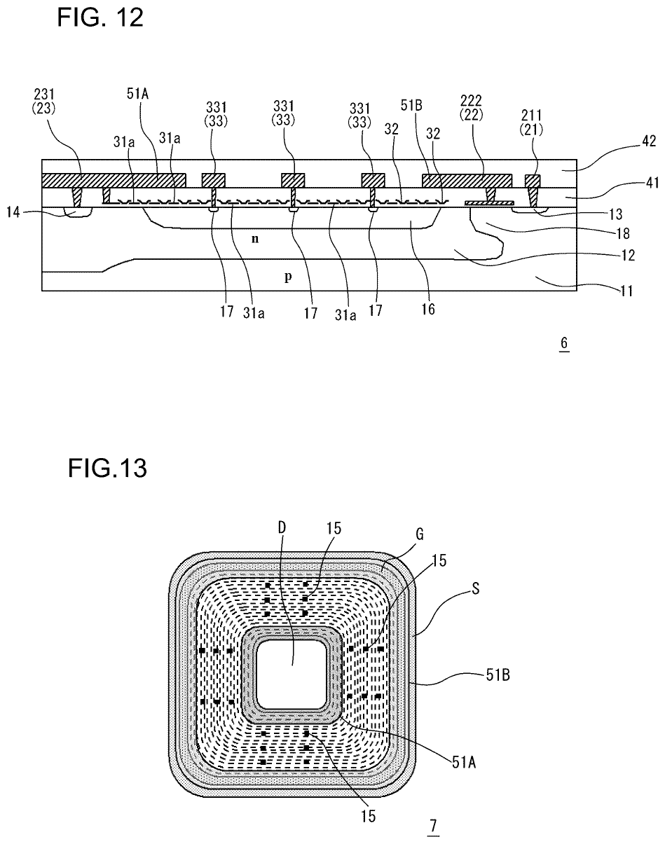

FIG. 12 is a cross-sectional view similarly showing the structure of the semiconductor device 6, which is a further modification as the fifth modification of the fourth modification. In the structure of FIG. 11, the cover metal 51 is arranged on the second insulating layer 42, but in this structure, the drain interconnection 231 in the first insulating layer 41 is extended on the first field plate 31a to the gate (G), and a part thereof is considered to be the cover metal 51A. Further, the gate interconnection 222 is extended on the first field plate 31a to the drain (D), and a part thereof is considered to be the cover metal 51B. In particular, since the influence of the positive charge of the foreign ion is large, the influence of the foreign ion may be more effectively reduced by extending the gate interconnection 222 on the low potential side on the first field plate 31a. Further, in the semiconductor device 6, as in the semiconductor device 3 of FIG. 9, the P-type layer (breakdown voltage improvement region) 16 and the plurality of N+ layers (auxiliary semiconductor region) 17 are provided locally on the P-type layer 16. Further, as described above, the semiconductor device 6 may not be provided with the P+ layer 15 and the N+ layer 17 directly under the cover metal 51, and furthermore, it may not be necessary to provide the auxiliary semiconductor region corresponding to all the first field plates 31. For this reason, the P+ layer 15 and the N+ layer 17 in FIG. 9 may be appropriately omitted. In FIG. 12, one or more cover metals may be further added between the cover metals 51A, 51B and the connection electrode 33, and between the adjacent connection electrode 33.

In the semiconductor devices 3 to 6, an example of providing P+ layer 15 in a straight line is shown in FIG. 6A, and a P+ layer 15 is set and connected to a first field plate 31 (a first field plate 31 selected in the semiconductor device 4 and the like). However, the P+ layer 15 may be connected at a plurality of locations on a single field plate.

For example, FIG. 13 is a plan view corresponding to FIG. 6 showing the structure of the semiconductor device 7 that is such a sixth modification according to one or more embodiments. The cross-sectional structure in this case is the same as in FIG. 8. Here, the P+ layer 15 is connected only to a part of the (three) first field plates 31 in which the P+ layer 15 is provided on a part of the circumference, and the other field plates 31a are not connected to the P+ layer 15, and are considered to be in a floating state. However, as shown in FIG. 13, the P+ layer 15 (and the connection electrode 33, etc.) are provided at eight locations for each first field plate 31 in the circumferential direction. That is, the surface potential at these eight locations is common, and this potential becomes the potential of the first field plate 31.

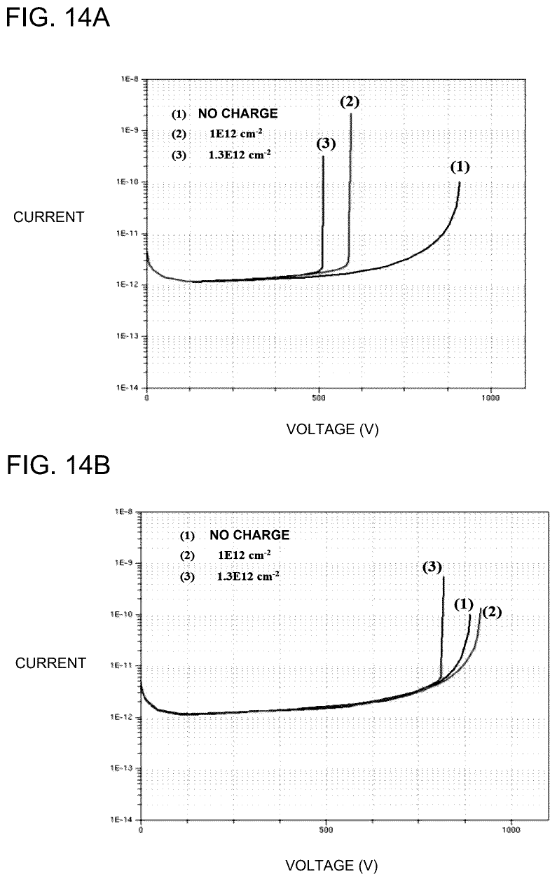

FIG. 14A is a diagram illustrating the result of the current-voltage characteristics between the source electrode 21 and the drain electrode 23 in the semiconductor device 7 of FIG. 13 at the turned off state by simulation, when P+ layers 15 connected to the first field plate 31 are not provided. FIG. 14B is a diagram illustrating the result of the current-voltage characteristics between the source electrode 21 and the drain electrode 23 in the semiconductor device 7 of FIG. 13 at the turned off state by simulation, when the P+ layer 15 connected to the first field plate 31 is provided and connected to a part of the first field plate 31. In the calculation, the P+ layer 15 is assumed to be arranged the entire circumference along the corresponding first field plate 31.

Here, FIGS. 14A and 14B shows the results when there is no fixed charge assuming a foreign ion on the second insulating layer 42 (plot line 1), when there is a unit charge of 1×10¹² cm⁻² (plot line 2), and when there is a unit charge of 1.3×10¹² cm⁻² (plot line 3). Here, the voltage (horizontal axis) at which the current (vertical axis) rises rapidly corresponds to the breakdown voltage.

From the results, there is no significant difference between when there is no fixed charge (plot line 1), the case where there is no P+ layer 15 connected to the first field plate 31 (FIG. 14A) and the case where P+ layer 15 connected to the first field plate 31 is provided (FIG. 14B). However, when there is a fixed charge (plot line 2) and (plot line 3) when the P+ layer 15 connected to the first field plate 31 is provided (FIG. 14B), the breakdown voltage is improved than when there is no P+ layer 15 connected to the first field plate 31 (FIG. 14A). That is, the above structure may allow mitigates the breakdown voltage drop due to the adsorption of foreign ions in the semiconductor device, and that the above structure may be effective in improving the breakdown voltage.

All of the above examples were examples of adopting the above structure in the drift layer in the LDMOSFET, but the above structure may be adopted in other semiconductor devices or in parts other than the drift layer in other semiconductor devices. Such a portion includes, for example, a termination region arranged outside the active region when the power semiconductor circuit is arranged in the active region, which is positioned in the semiconductor substrate. Even in the termination region, a structure that improves the breakdown voltage is used in order to suppress the electric field concentration during the off period, and the above structure may be adopted. Further, the semiconductor circuit may be a vertical semiconductor circuit through which an operating current flows in the longitudinal direction (in the thickness direction of the semiconductor layer). The semiconductor circuit may be a lateral semiconductor device in which an operating current flows laterally (in the width direction of the semiconductor layer).

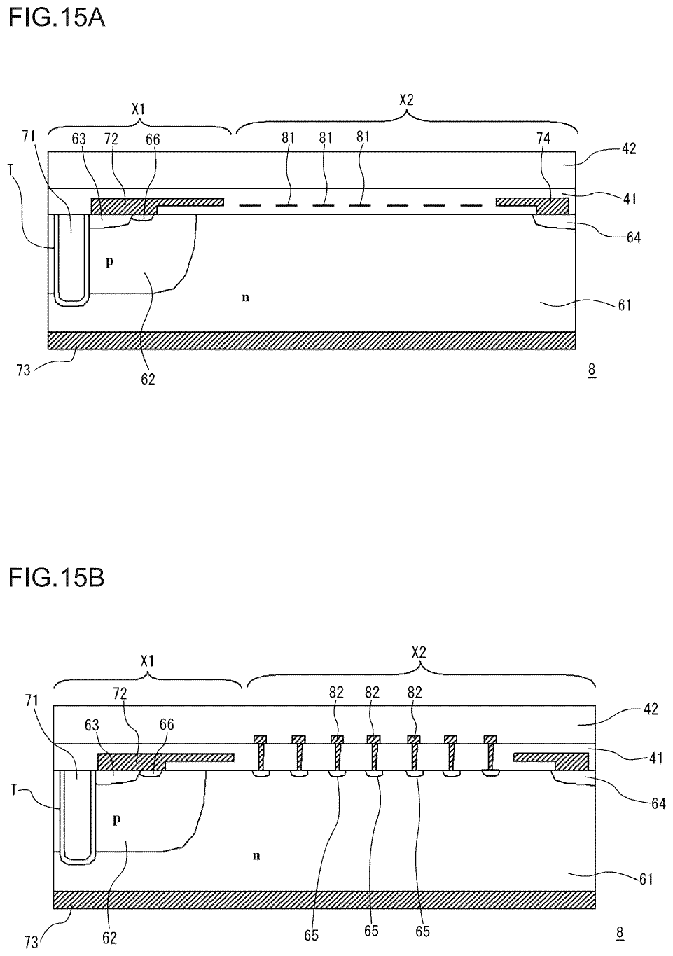

FIGS. 15A and 15B are cross-sectional views corresponding to FIGS. 2 and 4 showing the structure of a semiconductor device 8 (seventh modification) that serves as an example of a vertical semiconductor circuit such as a MOSFET. In the semiconductor device 6, the P-type layer 62 is arranged in the N-type layer (first semiconductor region) 61 that serves as the drain side in the active region X1. Further, a trench T penetrating the P-type layer 62 is arranged from the surface, and the gate electrode 71 is arranged in the trench T interposed a thin gate oxide film. On the surface of the P-type layer 62 adjacent to the trench T, the N+ layer 63 serves as a source region and the P+ layer 66 for contact with the P-type layer 62 are arranged, and the source electrode 72 is arranged on the N+ layer 63 and the P-type layer 62 (P+ layer 66). A drain electrode 73 is arranged on the back side of the N-type layer 61.

In FIG. 15A, the termination region 64 having an N+ layer and the termination electrode 74 connected thereto are arranged on the N-type layer 61 of the breakdown voltage improvement region X2 outside the active region X1 (right side in the figure). On the N-type layer 61 between the source electrode (electrode on the low potential side) 72 and the termination electrode (electrode on the high potential side) 74, the field plates 81 are separated from each other and arranged in a plurality so as to be capacitively coupled. Each of the field plate 81 is perpendicular to the Y axis direction, and when the semiconductor device is viewed from above, each field plate 81 and the breakdown voltage improvement region X2 are arranged so as to surround the active region X1.

The field plate 81 whose potential is to be uniquely fixed is connected to the P+ layer (auxiliary semiconductor region) 65 provided on the surface of the N-type layer 61 interposed the connection electrode 82. The connection electrode 82 performs the same operation as the connection electrode 33 described above, and the P+ layer 65 performs the same operation as the above-described P+ layer 15. It is clear that the same effect as that of the semiconductor device 1 may be obtained in the semiconductor device 6. At this time, since the P+ layer 65 in the breakdown voltage improvement region X2 is arranged shallowly at the same impurity concentration as the P+ layer 66 in the active region X1, they may be formed simultaneously in the manufacturing process.

When the field plate 81 is not provided, the P+ layer that serves as the guard ring used in the conventional semiconductor device is arranged in a circular shape in the circumferential direction so as to surround the active region X1 in order to control the spread of the depletion layer in the semiconductor layer, whereas the P+ layer 65 is arranged shallowly and locally as described above.

However, the P+ layer 65 may be arranged so as to surround the active region X1 as in this guard ring structure. At this time, one or more P+ layers 65 that are not connected to the field plate 81 interposed the connection electrode 82 may be provided between the P+ layers 65 connected to the field plate 81 interposed the connection electrode 82.

In the example of FIG. 15, only one layer of the field plate 81 is provided, but the field plate may be a two-layer structure as described above. Further, as shown in FIG. 9, the P-type layer 16 and the N+ layer (auxiliary semiconductor region) 17 are provided on the surface of the N-type layer 12, a P-type layer (reduced surface field layer) corresponding to the P-type layer 16 may be arranged on the breakdown voltage improvement region X2 of the N-type layer 61, and an N+ layer of the auxiliary semiconductor region corresponding to a plurality of N+ layers 17 may be arranged locally on the P-type layer, and the N+ layer and the field plate 81 may be connected interposed a connecting electrode corresponding to the connection electrode 33.

In this way, the structure in which the field plate and the auxiliary semiconductor region are combined may be used as in the semiconductor device having a structure in which a depletion layer is arranged where the semiconductor device is off and in which the breakdown voltage in this case is improved (to suppress the formation of a region with a locally high electric field strength). Further, in the semiconductor layer, other layers may be appropriately added or deleted as necessary. Further, in the above example, it is clear that the same configuration may be applied even when all the p-type and n-type in the semiconductor are reversed.

In the related technique described above, when impurity ions are adsorbed from the outside, for example, on the surface protective film, the potential of the field plate that is not potentially fixed may be affected by this charge. As a result, the surface potential of the semiconductor layer is also affected by this charge, and it may not be possible to properly divide the surface potential of the semiconductor layer as described above. The semiconductor device according to one or more embodiments may stably achieve a high breakdown voltage.

Although one or more embodiments have been described as above, the statements and drawings that form part of the disclosure should not be understood to limit the technical scope. From the disclosure, various alternative embodiments, examples, and operational techniques may become apparent to those skilled in the art. Thus, the technical scope may include various embodiments not described herein. For example, the first field plate 31, the second field plate 32, and the field plates 81, and 91 may not have to have the same width, and the intervals between them may not have to be the same, and the gradual width and spacing may be changed as appropriate.

1. A semiconductor device comprising:
a high potential region electrically connected with an electrode of a high potential side;
a low potential region electrically connected with an electrode of a low potential side;
a breakdown voltage improvement region arranged between the high potential region and the low potential region, comprising a first semiconductor region of a first conductive type;
a plurality of field plates, each of the field plates arranged facing a surface of the breakdown voltage improvement region interposed an insulating layer, the field plates arranged in an array direction so as to capacitively coupled each other between the high potential region and the low potential region, and extending in a direction that intersects the array direction;
an auxiliary semiconductor region of a second conductive type locally arranged corresponding to at least one field plate selected from the field plates on the surface of the first semiconductor region; and
a connection electrode connecting the auxiliary semiconductor region with the field plate selected from the field plates.

2. The semiconductor device according to claim 1, wherein
a field plate of the selected from the field plates arranged on a side of the high potential region is connected to the electrode on the high potential side.

3. The semiconductor device according to claim 2, wherein
a field plate of the selected form the field plates arranged on a side of the low potential region is connected to the electrode on the low potential side.

4. The semiconductor device according to claim 1, wherein
in a planar view, a ratio of a length of the auxiliary semiconductor region to a length of the field plate along an extension direction of the field plate is 1/10 or less.

5. The semiconductor device according to claim 3, wherein
in a planar view, a ratio of a length of the auxiliary semiconductor region to a length of the field plate along an extension direction of the field plate is 1/10 or less.

6. The semiconductor device according to claim 1, wherein
three or more auxiliary semiconductor regions electrically connected to the field plate are not arranged in a straight line in planar view.

7. The semiconductor device according to claim 3, wherein
three or more auxiliary semiconductor regions electrically connected to field plates that are not selected from the field plates are not arranged in a straight line in planar view.

8. The semiconductor device according to claim 1, wherein
the auxiliary semiconductor region is arranged in a region where the field plate is partially cut out in an extension direction of the field plate.

9. The semiconductor device according to claim 3, wherein
the auxiliary semiconductor region is arranged in a region where the field plate is partially cut out in an extension direction of the field plate.

10. The semiconductor device according to claim 1, wherein the field plates comprise:
a first field plate group comprising a plurality of first field plates arranged at intervals in a planar view; and
a second field plate group comprising a plurality of second field plates, each of the second field plates arranged between two adjacent first field plates, each of the second field plates capacitively coupled with the two adjacent first field plates.

11. The semiconductor device according to claim 3, wherein the plurality of field plates comprises:
a first field plate group comprising a plurality of first field plates arranged at intervals in a planar view; and
a second field plate group comprising a plurality of second field plates, each of the second field plates arranged between two adjacent first field plates, each of the second field plates capacitively coupled with the two adjacent first field plates.

12. The semiconductor device according to claim 1, further comprising
a metal plate arranged above a field plate of the field plates interposed the insulating layer, wherein
the auxiliary semiconductor region is not provided on the surface of the first semiconductor region directly below the metal plate.

13. The semiconductor device according to claim 3, further comprising
a metal plate arranged above a field plate of the field plates interposed the insulating layer, wherein
the auxiliary semiconductor region is not provided on the surface of the first semiconductor region directly below the metal plate.

14. The semiconductor device according to claim 12, wherein
the metal plate is connected to an electrode of the high potential side or an electrode of the low potential side.

15. The semiconductor device according to claim 13, wherein
the metal plate is connected to an electrode of the high potential side or an electrode of the low potential side.
